(19) United States
(12) Patent Application Publication
(10) Pub. No.: US 2013/0270712 A1
(43) Pub. Date: Oct. 17, 2013

(54) Through silicon via structure and method of fabricating the same

(71) Applicants: Hsin-Yu Chen, Nantou County (TW); Yu-Han Tsai, Kaohsiung City (TW); Ching-Li Yang, Ping-Tung Hsien (TW); Home-Been Cheng, Keelung City (TW)

(72) Inventors: Hsin-Yu Chen, Nantou County (TW); Yu-Han Tsai, Kaohsiung City (TW); Ching-Li Yang, Ping-Tung Hsien (TW); Home-Been Cheng, Keelung City (TW)

(21) Appl. No.: 13/447,293

(22) Filed: Apr. 16, 2012

(51) Int. Cl. H01L 23/48; H01L 21/768

(52) U.S. Cl. 257/774; 438/653; 257/E21.584; 257/E23.011

(57) ABSTRACT

A through silicon via structure and a method of fabricating the through silicon via structure are disclosed. After an interlayer dielectric is formed, a via hole is then formed to pass through the interlayer dielectric; thereafter, a dielectric liner is formed within the via hole and extends onto the interlayer dielectric; thereafter, the via hole is filled with a conductive material; and a chemical-mechanical polishing process is performed to planarize the conductive material, using the dielectric liner on the interlayer dielectric as a stop layer of the chemical-mechanical polishing process.

### BACKGROUND OF THE INVENTION

1. Field of the Invention

The present invention relates to a fabrication method and a structure of a through silicon via (TSV).

2. Description of the Prior Art

In the field of semiconductor technology, a TSV structure is utilized for interconnect between die and die to provide electrical connection of the devices on each level, such that the linking distances of devices disposed on a chip can be remarkably reduced, and, in turn, the overall operation speed can be effectively increased. Accordingly, the TSV structure is particularly suitably used in devices for which good performance and high integration fabrication process are required. For example, the TSV structure can be employed in a structure of wafer-level package utilized in micro electronic mechanic system (MEMS), photo-electronics and electronic devices.

Ordinarily, the TSV structure is obtained by forming a via hole on the front side of a wafer by etching or laser process and filling the via hole with a conductive material, such as polysilicon, copper or tungsten, to form a conductive path (i.e. the interconnect structure). Finally, the back side of the wafer, or die, is thinned to expose the conductive path. However, the via hole is formed on the front side of the wafer, and after the conductive material is filled into the via hole, a surplus of the conductive material located on the interlayer dielectric is often removed by performing a chemical-mechanical polishing (CMP) process. This process tends to result in a loss of the interlayer dielectric, and, in turn, add difficulty for integrating the TSV process and other element (such as MOS) processes.

Therefore, there is still a need for a novel and easy fabrication method of TSV structures.

### SUMMARY OF THE INVENTION

One objective of the present invention is to provide a method of fabricating a TSV structure and a TSV structure, in which the production yield is excellent and the production cost is low.

According to one embodiment of the present invention, a method of fabricating a TSV structure includes steps as follows. First, a substrate is provided. The substrate includes a device region and a TSV region. A device is disposed in the device region. Thereafter, an interlayer dielectric is formed to cover the device region and the TSV region. Thereafter, a via hole is formed within the substrate in the TSV region. The via hole is allowed to pass through the interlayer dielectric. Thereafter, a dielectric liner is formed within the via hole and on the interlayer dielectric. The via hole is filled with a first conductive material. A chemical-mechanical polishing process is performed on the substrate to planarize the first conductive material using the dielectric liner on the interlayer dielectric as a stop layer of the chemical-mechanical polishing process.

According to another embodiment of the present invention, a TSV structure includes a substrate, a device, an interlayer dielectric, a via hole, a conductive material and a dielectric liner. The substrate includes a device region and a TSV region. The device is on the substrate in the device region. The interlayer dielectric covers the substrate and the device and is planarized. The via hole passes through the interlayer dielectric and the substrate in the TSV region. The via hole includes a sidewall. The conductive material is disposed within the via hole. The dielectric liner is disposed between the conductive material and the sidewall and extends onto the interlayer dielectric.

According to one embodiment of the present invention, a TSV is formed before the formation steps of the contact plugs for the device, and accordingly the dielectric liner of the TSV can be utilized as a re-cap layer, which is usually additionally formed on the interlayer dielectric in conventional technology, to reduce production cost by omitting the conventional step of additionally forming the re-cap layer. Furthermore, such dielectric liner may serve as a stop layer for a planarization process, such as CMP process, for forming the TSV structure without forming an additional stop layer. Furthermore, the interlayer dielectric will not suffer loss from the CMP process for the TSV. Furthermore, since the contact plugs are formed after the TSV is formed, the contact plugs will not experience the CMP process for the TSV formation, and accordingly the height of the contact plugs will not decrease due to the CMP process. Therefore, the production cost may be reduced and the yield may increase.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 and 2 are schematic cross-sectional views illustrating a method of fabricating a TSV structure;

FIG. 3 is a flow chart illustrating a method of fabricating a TSV structure according to one embodiment of the present invention;

FIGS. 4 to 6 are schematic cross-sectional views illustrating a method of fabricating a TSV structure according to one embodiment of the present invention;

FIG. 7 is a schematic cross-sectional view illustrating a TSV structure according to one embodiment of the present invention; and

FIG. 8 is a schematic cross-sectional view illustrating a TSV structure according to another embodiment of the present invention.

### DETAILED DESCRIPTION

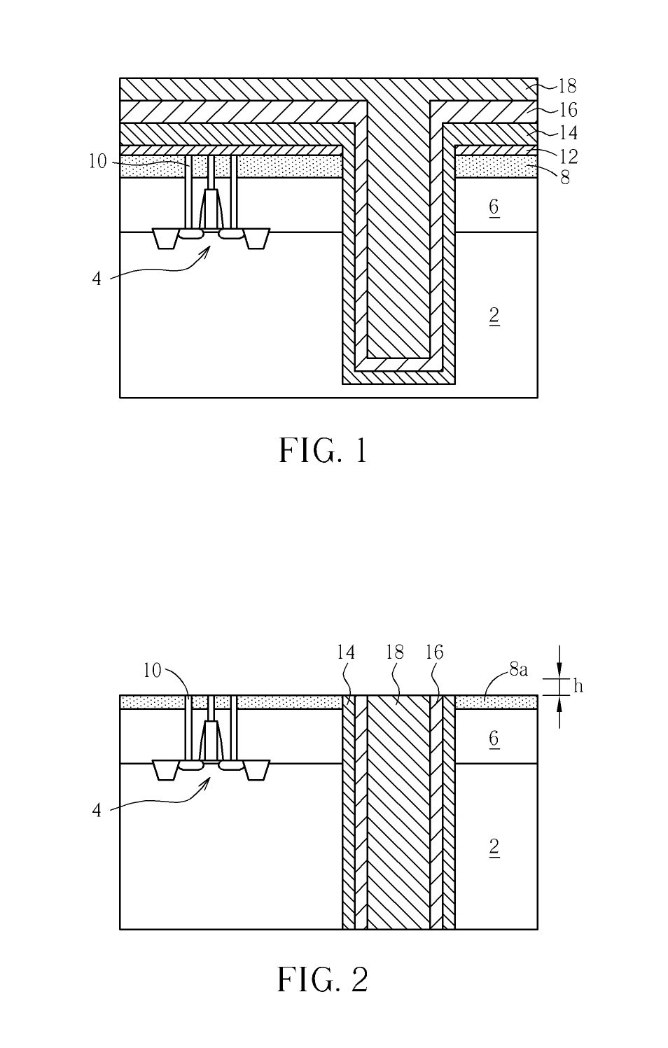

FIGS. 1 and 2 are schematic cross-sectional views illustrating a method of fabricating a TSV structure. A device 4 is disposed on a substrate 2. Thereafter, an interlayer dielectric 6 is disposed. The interlayer dielectric 6 is planarized. A re-cap layer 8 is formed on the interlayer dielectric 6, in consideration of a loss of the interlayer dielectric in following processes. Thereafter, contact plugs 10 are formed. Thereafter, a stop layer 12, such as silicon nitride layer, is formed. Thereafter, a via hole for TSV is formed and filled with a dielectric liner 14, a barrier layer 16 and a conductive material 18 in this order. Thereafter, a chemical-mechanical polishing process is performed to remove the re-cap layer 8 and excess of barrier layer 16 and conductive material 18 above the contact plugs 10, as shown in FIG. 2. Thereafter, a back side thinning process is performed to accomplish the TSV structure. In the CMP process, the stop layer 12 provides signals for preparation to stop polishing. Since it is required to completely remove the stop layer 12 on the contact plugs 10, the polishing needs stopping on the re-cap layer 8, resulting in loss of thickness. FIG. 2 schematically illustrates the remaining re-cap layer 8a and the lost thickness h. Accordingly, in a design for a thickness of an overall interlayer dielectric, which may include an interlayer dielectric and a re-cap layer, a possible to-be-removed thickness must be added to form the re-cap layer, and thus both processing time and material can be wasted.

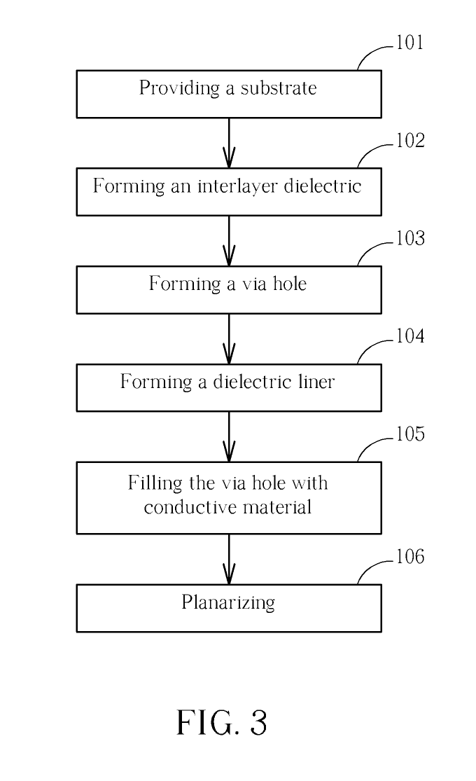

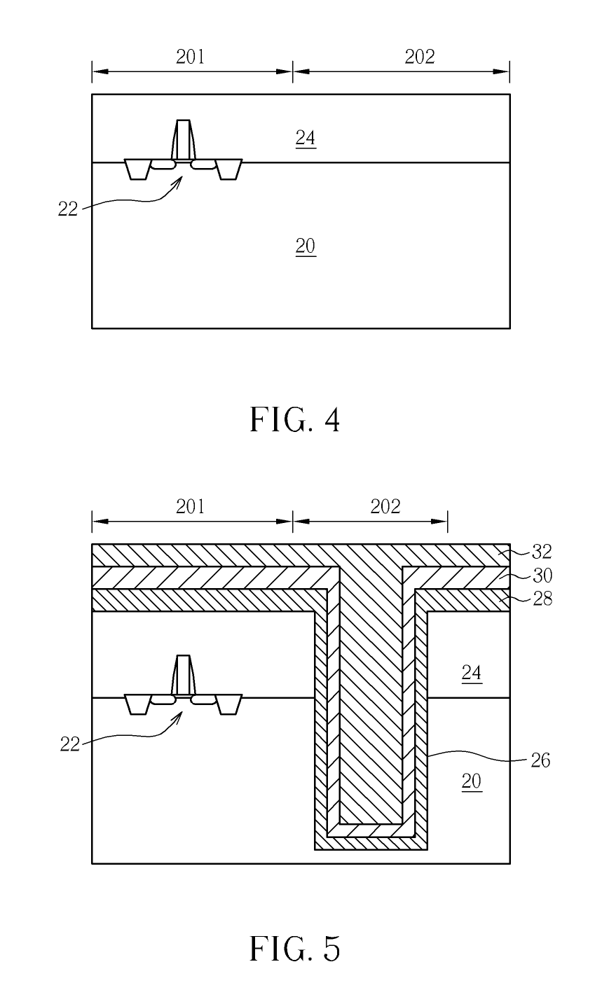

Please refer to FIGS. 3 to 6. FIG. 3 is a flow chart illustrating a method of fabricating a TSV structure according to one embodiment of the present invention. FIGS. 4 to 6 are schematic cross-sectional views illustrating a method of fabricating a TSV structure according to one embodiment of the present invention. It should be noted that the drawing size of the figures does not in a real scale ratio and is just schematic for reference. The same elements of the embodiments may be marked with the same referral numbers. First, referring to FIGS. 3 and 4, Step 101 is carried out to provide a substrate 20. The substrate 20 may comprise monocrystalline silicon, gallium arsenide (GaAs), or other material known in the art. The substrate thickness may be about 600 to 1000 micrometers, but not limited thereto. The substrate 20 includes a device region 201 and a TSV region 202. A device 22, such as MOS transistor or other device or element, is disposed in the device region 201. Thereafter, Step 102 is carried out to form an interlayer dielectric 24 on the substrate 20 and covering the device region 201 and the TSV region 202. The interlayer dielectric 24 may be a mono-or multi-layer. The material may be for example SiO₂, SiC, Si₃N₄, a low dielectric constant material, or the like. The interlayer dielectric may be formed through CVD, SOG (spin-on-glass), or other processes. The bottom layer of the interlayer dielectric 24 may be preferably an oxide layer. The interlayer dielectric 24 may be further planarized using for example a CMP process. Its final thickness may be optional as desired or required.

Thereafter, referring to FIG. 3 and FIG. 5, Step 103 is carried out to dispose a via hole 26 in the TSV region 202. The via hole 26 may be formed through for example microlithography and etching processes, or the via hole 26 may be formed using a patterned photo resist layer without using a hard mask layer (for example a patterned silicon nitride layer). The size of the via hole 26 maybe for example from about 6 micrometers (hole diameter)×about 40 micrometers (depth) to about 25 micrometers (hole diameter)×about 150 micrometers (depth), but not limited thereto. Thereafter, Step 104 is carried out to form a dielectric liner 28 within the via hole 26. The dielectric liner 28 is allowed to cover the side wall of the via hole 26 and extend onto the interlayer dielectric 24. In the present invention, the dielectric liner 28 will be with the interlayer dielectric 24 together in the completed TSV structure to serve as an overall interlayer dielectric within an integrated circuit structure. The dielectric liner 28 may be formed using for example a CVD process. A dielectric material which can serve as a dielectric liner of a TSV structure can be considered as material suitable for the dielectric liner of the TSV structure. That is, it is necessary for the dielectric material for forming the dielectric liner of the TSV structure to have properties of electric insulation, in order to provide a good insulation between the conductive material and the substrate. It is preferred that the dielectric liner has properties of moisture blocking to prevent the moisture from invading the TSV structure. When the dielectric liner 28 is one suitable for the TSV structure, it may also be one suitable to serve as an interlayer dielectric. Accordingly, the material, for example, silicon oxide, silicon nitride, silicon oxonitride or other suitable material, may be utilized. The dielectric liner may be a mono- or multi-layer. Due to the effect of step coverage during CMP process, the thicknesses of the dielectric liner 28 located at different places may be different and depend on material, process conditions and location and accordingly be optional. For example, a silicon oxide layer as the dielectric liner 28 may be formed through a CVD process at 300 to 400° C. using tetraethoxysilane (TEOS) as a silicon source. The thickness of the resulting silicon oxide layer may be for example about 1000 angstroms to about 2000 angstroms on the side wall of the via hole 26 (substantially vertically) and for example about 3000 or more angstroms on the interlayer dielectric 24 (substantially horizontally). Since the dielectric liner is demanded to have a function of protecting the TSV structure and the interlayer dielectric is demanded to be formed fast, the dielectric liner 28 will have a relatively great density, and the interlayer dielectric 24 in a portion immediately underlying the dielectric liner 28 will have a relatively less density in the final structure. In other words, the dielectric liner may have a density greater than the density of the interlayer dielectric 24.

Thereafter, Step 105 is carried out to fill the via hole 26 with a conductive material 32. Before the via hole 26 is filled with the conductive material 32, a barrier layer or seed layer 30 may be optionally formed on the dielectric liner 28 within the via hole 26. The barrier layer or seed layer 30 may be formed by conventional technology. With respect to cupper conductive material, the barrier layer may include for example Ta, TaN (tantalum nitride), Ti, TiN or a combination thereof. Thereafter, the via hole 26 is filled with conductive material 32, which may include for example copper, tungsten, aluminum or other suitable material. The filling of the conductive material may be accomplished through for example electroplating, sputtering, CVD, electroless plating/electroless grabbing, or the like.

Thereafter, referring to FIG. 3 and FIG. 6, Step 106 is carried out to perform a planarization process to polish the conductive material 32. For example, a CMP process is performed using the dielectric liner 28 as a stop layer i.e. to polish and remove the conductive material 32 and the barrier layer or seed layer 30 above the interlayer dielectric 24 until the dielectric liner 28 above the interlayer dielectric 24 is exposed. A portion of the dielectric liner 28 may be removed to loss some thickness, while there is still a remaining thickness of the dielectric liner 28 sufficient for protecting the underlying interlayer dielectric 24. Accordingly, the interlayer dielectric 24 will not be damaged or have a loss during the CMP process for making the TSV structure. The remaining thickness of the dielectric liner 28 may serve as a re-cap layer on the interlayer dielectric 24, using the height of the remaining dielectric liner 28 as the height of re-cap layer. After the planarization, the dielectric liner 28 onto the interlayer dielectric 24 and the conductive material 32 together present a planarized plane.

After Step 106, one or more contact plugs for the device 22 may be further formed. The formation of the contact plugs may be formed using a conventional technology. For example, a hard mask layer is formed to cover the dielectric liner 28; the hard mask layer is patterned by etching through a photolithographically patterned photo resist layer to have at least one opening; the dielectric liner 28 and the interlayer dielectric 24 exposed from the at least one opening are etched, resulting in at least one contact hole passing through the dielectric liner 28 and the interlayer dielectric 24 to expose the substrate 20 and/or the device 22 (for example, gate, source and drain electrodes of a MOS transistor); the hard mask layer is removed; and, thereafter, the contact hole is filled with conductive material, which may include for example cupper, tungsten, aluminum, and the like. This conductive material may be the same as or different from the conductive material for TSV. A planarization process, such as CMP process, may be optionally further performed. The contact plugs 34 are thus formed to pass through the dielectric liner 28 and the interlayer dielectric 24 to contact the device 22 and may be allowed to connect the first layer of metal of the metal interconnect structure in subsequent processes.

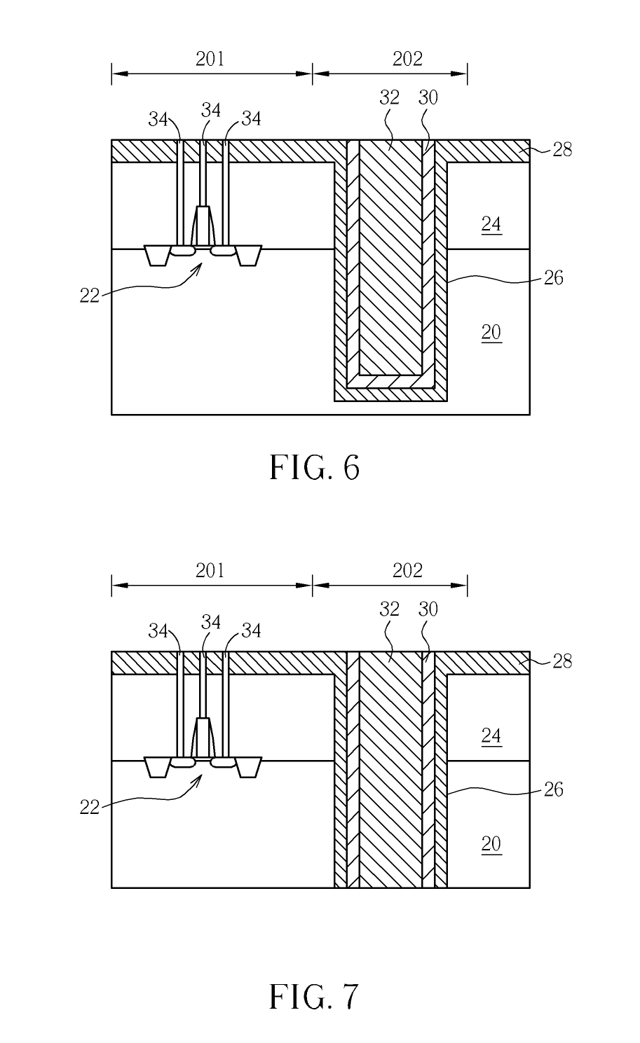

Thereafter, please refer to FIG. 7. Elements or devices, such as multi-layered metal interconnect, passivation layer, and so on, formed on the front side of the wafer from back-end processes are not shown in the drawings. As shown in FIG. 7, a thinning process is performed on the back side (i.e. the side which the interlayer dielectric is not formed on) of the substrate 20 to expose the conductive material 32 of TSV, to accomplishing the TSV structure. The thinning process can be performed by carrying out a step of polishing the back side of the substrate 20 using for example a CMP process.

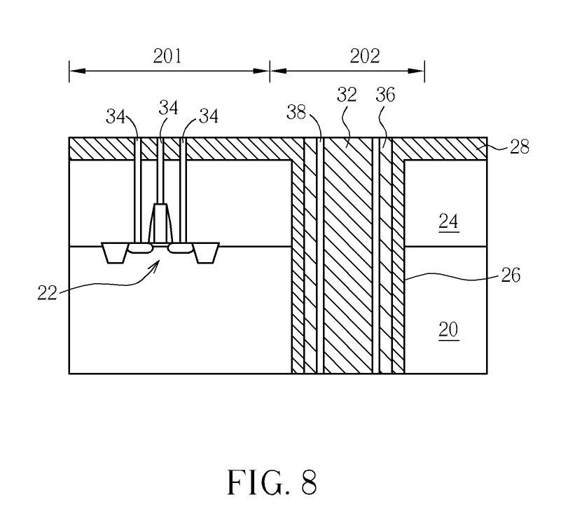

FIG. 8 illustrates a TSV structure according to another embodiment of the present invention. The TSV structure further includes a barrier layer 36 and a seed layer 38. The barrier layer 36 is formed between the conductive material 32 and the dielectric liner 28, and the seed layer 38 is formed between the barrier layer 36 and the conductive material 32.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating a through silicon via (TSV) structure, comprising:
providing a substrate comprising a device region having a device and a TSV region;
forming an interlayer dielectric covering the device region and the TSV region;
forming a via hole within the substrate in the TSV region and allowing the via hole to pass through the interlayer dielectric;
forming a dielectric liner within the via hole and allowing the dielectric liner to extend onto the interlayer dielectric;
filling the via hole with a first conductive material; and
performing a chemical-mechanical polishing process on the substrate to planarize the first conductive material using the dielectric liner on the interlayer dielectric as a stop layer of the chemical-mechanical polishing process.

2. The method of fabricating a TSV structure of claim 1, further comprising forming a barrier layer between the first conductive material and the dielectric liner within the via hole.

3. The method of fabricating a TSV structure of claim 1, further comprising forming a seed layer between the first conductive material and the dielectric liner within the via hole.

4. The method of fabricating a TSV structure of claim 2, further comprising forming a seed layer between the first conductive material and the barrier layer within the via hole.

5. The method of fabricating a TSV structure of claim 1, further comprising forming at least one contact plug through the dielectric liner and the interlayer dielectric to contact the device.

6. The method of fabricating a TSV structure of claim 5, wherein, forming the at least one contact plug is carried out by performing photolithography and etch processes to form at least one contact hole through the dielectric liner and the interlayer dielectric, filling the contact hole with a second conductive material, and performing a planarization process.

7. The method of fabricating a TSV structure of claim 5, wherein, steps of forming the at least one contact hole are carried out after planarizing the first conductive material.

8. The method of fabricating a TSV structure of claim 1, wherein, forming the via hole within the substrate in the TSV region is carried out using photolithography and etch processes.

9. The method of fabricating a TSV structure of claim 1, wherein, the dielectric liner has a first density, the interlayer dielectric has a second density, and the first density is greater than the second density.

10. A through silicon via (TSV) structure, comprising:
a substrate comprising a device region and a TSV region;
a device on the substrate in the device region;
an interlayer dielectric covering the substrate and the device and planarized;
a via hole through the interlayer dielectric and the substrate in the TSV region, the via hole comprising a sidewall;
a conductive material disposed within the via hole; and
a dielectric liner disposed between the conductive material and the sidewall and extending onto the interlayer dielectric.

11. The TSV structure of claim 10, further comprising a barrier layer between the conductive material and the dielectric liner within the via hole.

12. The TSV structure of claim 10, further comprising a seed layer between the conductive material and the dielectric liner within the via hole.

13. The TSV structure of claim 11, further comprising a seed layer between the conductive material and the barrier layer within the via hole.

14. The TSV structure of claim 10, further comprising at least one contact plug through the dielectric liner and the interlayer dielectric to contact the device.

15. The TSV structure of claim 10, wherein the dielectric liner has properties of moisture blocking

16. The TSV structure of claim 10, wherein, the dielectric liner has a first density, the interlayer dielectric has a second density, and the first density is greater than the second density.

17. The TSV structure of claim 10, wherein the dielectric liner onto the interlayer dielectric and the conductive material together present a planarized plane.
